(19) United States
(12) Patent Application Publication
(10) Pub. No.: US 2018/0145241 A1
(43) Pub. Date: May 24, 2018

(54) INTEGRATED CIRCUIT WITH COOLING ARRAY

(71) Applicant: HAT TEKNOLOJI A.?., Levent-Sisli/Istanbul (TR)

(72) Inventor: Halil KILIC, AA Den Haag (NL)

(21) Appl. No.: 15/315,496

(22) PCT Filed: Jun. 1, 2015
(86) PCT No.: PCT/EP2015/001109

§ 371 Date: Dec. 1, 2016

(30) Foreign Application Priority Data
Jun. 2, 2014 (EP) PCT/EP2014/061335

(51) Int. Cl. H01L 35/32; H01L 23/38; H01L 27/16

(52) U.S. Cl. CPC H01L 35/32; H01L 35/325; H01L 27/16; H01L 23/38

(57) ABSTRACT

The invention relates to an integrated circuit cooling array, preferably for a microprocessor or cooling apparatus, consisting of a dielectric substrate with doped and distinguished areas for the realization of at least one microelectronic component forming an integrated circuit, and at least one thermoelectric component forming a cooling array. The cooling array is characterized in that the thermoelectric component 1 comprises at least one first contact area, at least one second contact area and at least one cooling section whereat the cooling section is arranged between the first and the second contact area and consists of at least one thermal element 29, which is supplied with voltage by the first contact area and the second contact area through a control unit, whereat the thermal element 29 consists of at least one doped layer and a second doped layer, which are in such a way connected by a bridge element 53, 58, 59, 73, 83, 84, 92 that the bridge element 53, 58, 59, 73, 83, 84, 92 rests only partially on the first doped layer and/or the second doped layer. By means of the cooling array according to the invention compact and/or more efficient integrated circuits may be realized, since a sufficiently free heat flow from the inside of the integrated circuit is guaranteed.

The invention relates to an integrated circuit cooling array, preferably for a microprocessor or cooling apparatus, consisting of a substrate with doped and distinguished areas for the realization of at least one thermoelectric component forming a cooling array. Additionally at least microelectronic component can be formed on or within the substrate, which is cooled by the integrated circuit cooling array.

Integrated circuits for the realization of preferably microprocessors generally consist of a complex arrangement of layers of metal, semiconductors or dielectric media, which are arranged in a certain layout and forming order on a substrate consisting of a dielectric medium. The option of realizing electronic circuits in a very confined space in that matter exists due to semiconductor technology, which comprises different methods for layer composition and doping. With the use of these methods layers of both well-defined thickness and well-defined shaping at submicron level as well as producing well-defined doping. The methods of sputter deposition, beam deposition, vapor coating, ion plating (physical vapor deposition), chemical vapor deposition, galvanic coating, ion implantation, neutron transmutation doping and diffusion doping are to be mentioned here.

Thus, it became possible to produce highly complex electronic circuits in a very limited space; however, with increasing performance of the electronic circuit, the power consumption increases as well. The increased power consumption is in return attended by an increased heat emission of the microelectronic elements of the integrated circuit, and, consequently, the overall heat generation of the same. The heat emitted from an integrated circuit, however, is harmful to the same, and may even result in a loss of their functioning ability when reaching a critical temperature, which may occasionally even be permanent. Therefore, either the performance of an integrated circuit and thus its complexity has to be reduced, or an active cooling of the integrated circuit has to occur. In connection with an active cooling system both particularly compact and very efficient integrated circuits can be realized. However, since the heat occurring in an integrated circuit first has to pass the same before reaching its surface, the power consumption and complexity of an integrated circuit is limited even with an active cooling system.

An active cooling in the inside of an integrated circuit is possible by use of so-called Peltier elements according to prior art. Peltier elements are a serial sequence of thermal elements, which consist of two components with varying electrical conductivity. Both components are connected by a so-called bridge, which is electrically conducting. Two thermal elements each are also connected by a bridge, so that each bridge provides an electric connection between a first component and a second component of the same or an adjoining thermal element. The two components are generally an n-doped semiconducting material and a p-doped semiconducting material. These two components are often connected electrically by mostly metallic bridges. Since the energy level of the conduction band of a p-doped semiconducting material differs from the energy level of the conduction band of an identical but n-doped semiconducting material, the heat energy is absorbed from the surroundings or the heat energy is emitted to the surroundings when the electrons pass from one of the components into other one, depending on whether the electrons pass from the first component into the second one or the other way round. During a current flow therefore the emission of heat from the contact area between a bridge and a component to the surroundings or the absorption of heat from the surroundings occurs, whereat the direction of the heat transport depends on the materials of the first and second components and the direction of the current flow. The surroundings are formed by the embedding material of the integrated circuit and the further microelectronic components.

The heat emitted from the warmer side of a Peltier element has to be dissipated with the aid of an outer cooling system, for example with the aid of a cooling device and a fan arranged thereon. If a Peltier element is arranged within an integrated circuit, the hate can be transported through heat channels to the surface of the integrated circuit and then be dissipated.

In spite of this cooling system, which can be achieved within an integrated circuit through Peltier elements, the power consumption and complexity of integrated circuits is limited. This may be due to limitations to the dissipation of sufficient heat per time unit from the inside of an integrated circuit to the outside, or due to the occurrence of local heat spikes, which cannot be selectively, i.e. locally, be reduced by an increased cooling level.

Patent application US 2009/0321909 A 1 discloses an integrated circuit with a layer structure and a cooling array. The integrated circuit comprises two layers featuring microelectronic components constituting an integrated circuit. A Peltier element is arranged in at least one of the layers in order to cool a certain area of the integrated circuit.

A further patent application US 2006/0102223 A1 discloses a cooling array for an integrated circuit, which comprises a substrate made of an isolating material with a grated surface and thermal electric elements arranged on the heights of said substrate surface, whereat one component of the thermoelectric elements is n-doped and arranged on one side of the heights, and the second component of the thermoelectric elements is p-doped and arranged on the opposite side of the heights. Both components are connected by a metallic bridge, which is arranged at the top of each height. Between two heights another metallic bridge is arranged to electrically connect a first and a second component each. The first components, the second components and the bridges form a Peltier element.

The British patent application GB 2 364 439 A discloses a semiconductor chip, which comprises a substrate, an integrated circuit arranged on the substrate and a thermoelectric cooling array for cooling the integrated circuit arranged on the back of the substrate. The cooling array is a Peltier element.

Finally, the patent application US 201370255741 A1 discloses an integrated circuit with an embedded heat exchanger and an embedded thermoelectric cooling array, whereat the heat exchanger features a heat sink section, which is coupled with the thermoelectric cooling array. The cooling array is also a Peltier element.

Against this background, the purpose of the invention at hand is to indicate an integrated circuit cooling array, which can be noticeably more compact compared to prior art, due to improved heat dissipation and due to the fact that the component or components, for instance microelectronic components realized on the same substrate, to be cooled can be selectively locally cooled. A further purpose of the invention is to realize improved cooling of microelectronic components of an integrated circuit with as little power consumption as possible.

In order to achieve this purpose, it is intended that the thermoelectric component comprises at least a first contact area, at least a second contact area and at least one cooling section, whereat the cooling section is arranged between the first and the second contact area and consists of at least one thermal element, which is supplied with voltage by the first contact area and the second contact area through a control unit, and whereat the thermal element consists of at least one first doped layer and at least one second doped layer, which are connected such by a bridge element, that the bride element rests only partially on the first doped layer and/or the second doped layer.

Further advantageous embodiments of the invention are characterized in the sub-claims.

According to the invention, the thermoelectric component comprises at least one first contact area and at least one second contact area. At least one cooling section is arranged between these two contact areas. The cooling section consists of at least one thermal element. The thermal element consists of a first doped layer and a second doped layer, which are electrically connected by a bridge element. The bridge element is arranged in such a way, that it rests only partially on the first doped layer and/or the second doped layer. The cooling section can be supplied with voltage through the first contact area and the second contact area through a control unit. If a cooling section consists of several thermal elements, adjoining thermal elements are also connected electrically by a bridge element with each other.

The first doped layer is preferably a n-doped semiconducting layer, and the second doped layer is preferably a p-doped semiconducting layer, whereat the reverse order is also possible. Such a cooling array is characterized in that the bridge element of the thermal element rest only partially on either the first doped layer or the second doped layer or both layers. Therefore, it allows for the manipulation of the characteristics of heat transfer of a thermoelectric component consisting of one or more such thermal elements, without the need for a change in the essential “chip design”. A minimized contact area between bridge element and a doped layer thus results in an increase of current density in the contact area and therefore in an increase of the heat absorption or emission at said contact area. That way, not only the cooling capacity can be adjusted to the spatial distribution of the heat emission in a certain integrated circuit, but also to the strength of the heat emission, which allows for a lower power demand of the cooling array.

With the integrated circuit cooling array according to the invention a length of a section of the bridge element (53, 58, 59, 73, 83, 84, 92) resting on the first or second doped layer x, a length of the first or second doped layer y and a width of the first or second doped layer z comply with the conditions 0.2≤x/y≤0.5 and z≥x. y and z can, for instance, be in the range between 1 μm and 1 cm. Smaller dimensions are more difficult to produce, and thus more expensive, but possible as well. Greater dimensions are also possible. The dimensions of x, y and z can be chosen according to the purpose of the integrated circuit cooling array, whereat a main aspect is the cooling power per unit area and the cooling power distribution. Accordingly, the values of x, y and z can vary within a thermoelectric component, as long as the said conditions are met.

The at least one thermoelectric component can be arranged on the substrate or within the substrate. A thermoelectric component arranged on the substrate can pass the emitted heat from the integrated circuit to the surrounding air or a cooling device. A thermoelectric component arranged within the substrate serves for the transport of heat from the inside of the integrated circuit to its surface.

Preferably, a cooling section of a thermoelectric component consists of several thermal elements, which are connected in series between the first and the second contact area each and/or of several thermal elements which are each connected in series between the first and the second contact area and additional thermal elements are at least partially connected in parallel with individual thermal elements. With such a serial connection of thermal elements the first doped layer and the second doped layer of a thermal element are connected by a bridge element. Further the first doped layer of a thermal element is connected to the second doped layer of an adjoining thermal element by a further bridge element, and the second doped layer is connected with another adjoining thermal element by a further bridge element. In this case it might be intended that individual thermal elements of such a serial connection of thermal elements are connected in parallel with individual additional thermal elements. The latter serves a local increase of the cooling capacity.

It may be intended, the contact areas between the bridge element and the first and second doped layer differ from each other in regard to size. In this embodiment the bridge elements not only rest partially on the first doped layer and the second doped layer, but the contact areas of the first doped layers differ furthermore from the contact areas of the second doped layers in regard to their size. The sizes of the contact areas may vary from thermal element to thermal element, i.e. within one cooling section all contact areas may have different sizes, whereat the sizes of the contact area along a cooling section may increase continuously or may be formed periodically.

Preferably, several thermoelectric components exists, which are arranged within the substrate next to each other and/or above each other and/or that several adjoining thermoelectric components are arranged on the substrate. Thermoelectric components arranged next to each other allow for a distribution of the cooling capacity over the area. Thermoelectric components arranged above each other allow for an improved transport of the emitted heat from the inside of the integrated circuit to its surface. The cooling of the surface of the integrated circuit can additionally be realized through thermoelectric components arranged next to each other on the substrate, whereat the thermoelectric components may be in contact with a cooling device if necessary. Each thermoelectric component comprises, as detailed above, a second contact area and at least one cooling section arranged between the two contact areas, whereat said cooling section consists of at least one, preferably several thermal elements connected in series. The several thermoelectric components may be arranged in different levels of the substrate or be arranged on the same level next to each other, in order to allow for a locally selective cooling.

In a specific embodiment of the invention it may be intended that at least one thermal element in a lower position within the substrate and one thermal element in an upper position within the substrate are connected by a heat channel. Such a heat channel allows for a dissipation of the heat emitted by a thermal element and generally consists of a dielectric medium in order to prevent undesired electrical current, or of a metal in order to realize a quick heat transport, since metals are particular conductive in regard to heat. In the latter case the heat channel obviously has to be designed in such a way as to prevent an undesired short circuit.

Furthermore, it might be intended that several thermoelectric components are arranged above each other, whose first and second contact areas are connected by at least one permanent or switchable VIA-connection, whereat the switching of a VIA-connection occurs through the control unit. A VIA-connection (VIA=Vertical Interconnect Access) is an electric connection between two levels of an integrated circuit. Such a VIA-connection may be permanent, i.e. it is designed as a vertically extending circuit path throughout the integrated circuit, or it may be switchable, i.e. by comprising a transistor or another switchable component. The heat transport through the integrated circuit can thus be regulated by the control unit, and, at the same time, the power demand of the cooling array can be optimized, for selected thermoelectric components may be switched on or off on demand.

In a preferable embodiment several cooling sections are arranged to run parallel between the first and the second contact area. Each cooling section may thereby be supplied with voltage independently of the other ones. Additionally, at least two of the cooling sections may run in a horizontal angle a to each other or at least two cooling sections are arranged in a periodically alternating distance to each other. Cooling sections arranged next to each other allow for a distribution of the cooling capacity over a certain area. Due to the feature of the bridge resting partially on the first and second doped layer of a thermal element, areas with a higher cooling capacity and areas with a lower cooling capacity may be realized along one cooling section. With the help of cooling sections running in an angle to each other, additionally a locally higher cooling capacity may be reached, since the cooling capacity is higher in areas with a smaller distance between the cooling sections than in areas with a longer distance between the cooling sections. Also, a locally increased cooling capacity may be realized through one or more cooling sections which are arranged in a periodically changing distance to each other. The areas of the smallest distances between the thermal elements of the different cooling sections are always the areas with the highest cooling capacity.

The horizontal angle between two thermal elements of a cooling section or between two cooling sections or between two segments of two cooling sections measures between 5° and 85°, preferably between 30° and 40°, and particularly preferably between 10° and 20°.

Furthermore it can be intended, that several thermal elements or cooling sections of a thermoelectric component are arranged above each other in the substrate. A thermoelectric component is thus not necessarily reduced to a substrate level, but may extend to or span several substrate levels.

The cooling array can furthermore be designed in such a way, that a thermoelectric component contains a first contact area and several second contact areas, whereat at least one cooling section each is arranged between the first contact area and the second contact area. The first contact area may thus be surrounded by several second contact areas, whereat at least one cooling section is arranged between of the first contact area and each of the second contact areas. According to an embodiment several cooling sections extend from the first contact area in the form of a star structure to a second contact area or to several second contact areas surrounding the first one.

In order to monitor and control the cooling capacity, temperature sensors can be arranged between at least two cooling sections at different positions, which interact with the control unit to regulate the (local) cooling capacity. A mere monitoring of the cooling capacity is obviously also possible with the temperature sensors. With the aid of the mentioned embodiments of the cooling array and the temperature sensors an effective regulation of the cooling capacity can be achieved optimized in regard to position and cooling capacity, which simultaneously optimizes the power demand.

It can further be intended that the control unit comprises a circuit element for the selective voltage supply of one of several thermoelectric components or one of several cooling sections. Such a switching element also allows for a locally selective cooling capacity by switching individual thermoelectric components or individual cooling sections on or off.

In a preferable embodiment the control unit comprises a transistor, which supplies voltage through a blocking diode to the thermoelectric component, or the control unit comprises several transistors, which are connected in parallel and each supply voltage through a blocking diode to a thermoelectric component simultaneously or at staggered intervals in regard to other thermoelectric components. Such a control unit allows for the effective regulation of both a local and temporary cooling capacity. Furthermore, the control unit can also switch existing switchable VIA-connections independently from each other on or off.

The control unit comprises a programmable device with a high frequency pulse generator and a counting unit, which can be triggered by the pulse generator, whereat the VIA-connection between at least two thermoelectric components is switched in relation to the counter value of the counting unit by the control unit. Thus, e.g. a time-controlled regulation of the cooling capacity is possible, with which a periodic activation, i.e. voltage supply of one or more thermoelectric components or cooling sections is possible.

In an embodiment on the basis of prior art, the first doped layer of a thermal element is an n-doped layer, in particular made of a n-doped semiconducting material, and the second doped layer is a p-doped layer, in particular made of an p-doped semiconducting material. The semiconducting material may be a gallium arsenide or silicon carbide. The bridge element consists of a highly doped polysilicon, a metal or a metal alloy.

In a further embodiment of the integrated circuit according to the invention, at least one shielding layer may exist, which is arranged to adjoin to the warmer side of a thermoelectric component, whereat the shielding layer prevents an electric connection between the dielectric substrate and the warmer side of a thermoelectric component. The shielding layer can comprise an electrically isolating material, whereat the isolating material consists of a high-k and/or low-k dielectric medium, in particular silicon dioxide, AgO, TiO₂, HfO₂ or Al₂O₃.

Furthermore, the circuit according to the invention may feature at least one cooling layer, which contacts at least one bridge element on the cooler side of a thermoelectric component and consists of a heat conductive material. The cooling capacity of a thermoelectric element is distributed better with the help of such a cooling layer.

In a particular embodiment of the invention it may be intended, that the integrated circuit comprises at least one functional unit, which is arranged between the thermoelectric component and/or between cooling sections of one or more thermoelectric components and/or which is arranged at the warmer or cooler side of a cooling section.

The functional unit may comprise
a sensor, in particular a heat sensor or optical sensor,
a rectifier, in particular a diode,
a switching element, in particular a transistor, preferably a MOSFET such as IGFET, NMOS, PMOS, VMOS,
a control element,
a programmable device, in particular a microprocessor, a microcontroller or a programmable logic such as FPGA or PLD,
a memory element, such as DRAM, ROM, SRAM,
a solar panel,
a laser diode,
a light-emitting diode
a micro strip.

Such functional units consist of the above microelectronic components forming an integrated circuit, but already feature a certain functionality within the integrated circuit.

The integrated circuit according to the invention is designed for total electric currents between 0.5 pA and 500 mA, in particular between 1 mA and 200 mA, preferably between 20 μA and 120 μA and particularly preferably between 10 pA and 1 μA.

Furthermore, it can be intended that an intermediate layer is arranged between to thermoelectric components arranged above each other in the substrate, which determines a distance between the thermoelectric components. This distance preferably measures between 5 nm and 12 nm.

Further it is possible that the first and the second doped layer and the bridge element are connected with the substrate by an adhesive layer. Correspondingly, with cooling sections comprising several thermal elements, the first doped layer, the second doped layer and the bridge element are each connected with the substrate by adhesive layers. Such an adhesive layer prevents the dissolution of the individual layers. It is an intermediate layer made of a solid material.

In a particular embodiment it is possible, that a thermoelectric component is arranged on the substrate or in one of the upper layers of the substrate, whereat the heat produced by the microelectronic components of an integrated circuit is used for generating voltage. In this embodiment a thermoelectric component is arranged on the substrate or in an upper layer of the substrate, which is not used as a Peltier element and thus serves the active cooling of the integrated circuit, but which is used as a thermoelectric generator, i.e. which converts temperature difference caused by the waste heat of the integrated circuit to voltage (Seebeck effect). The voltage thus created can contribute to the running of the thermoelectric components or the running of the control unit.

In addition to the explanations provided hereinbefore, reference is made to the scientific publications “Performance of Novel Thermoelectric Cooling Module Depending on Geometrical Factors”, Journal of Electronic Materials, Vol. 44, No. 6 and “Influence of Geometrical Factors on Performance of Thermoelectric Material Using Numerical Methods” Journal of Electronic Materials, Vol. 44, No. 6, the disclosure of which is incorporated herein in its entirety.

The invention is further explained with the help of the figures.

It shows

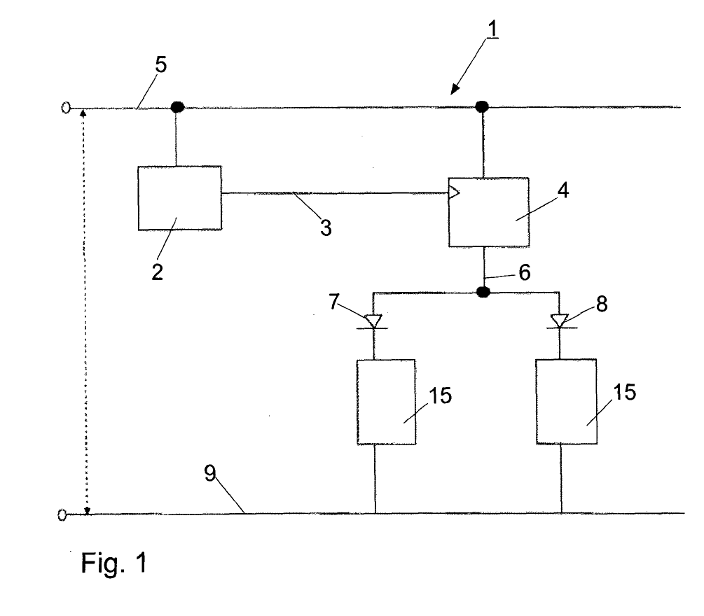

FIG. 1 a circuit diagram for a thermoelectric component of an integrated circuit with two cooling elements,

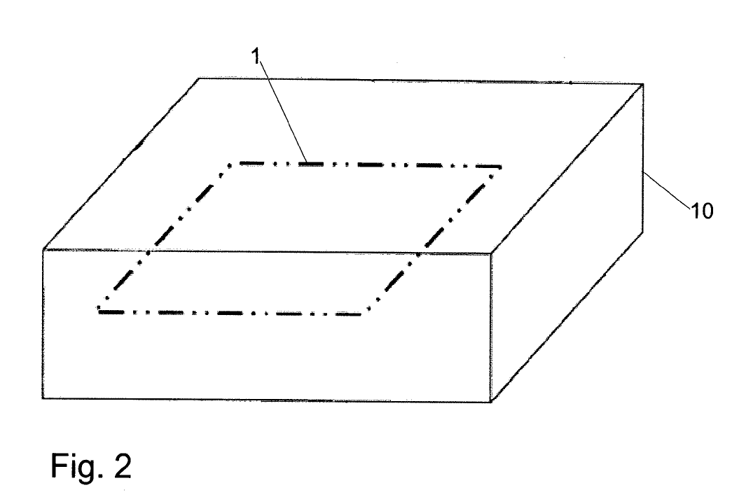

FIG. 2 a schematic view of a possible mounting position of the thermoelectric component in a perspective view,

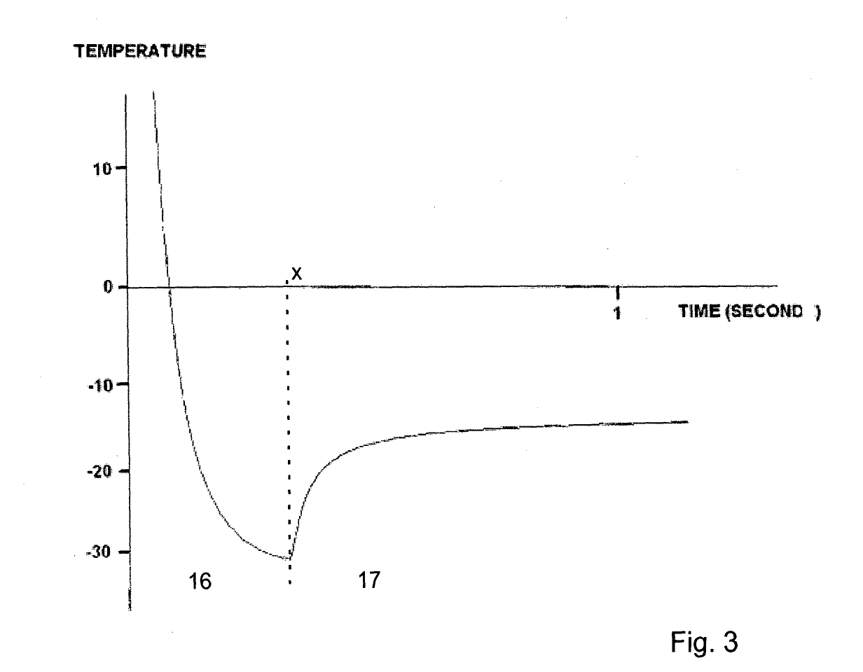

FIG. 3 a temperature-time diagram of a cooling flow,

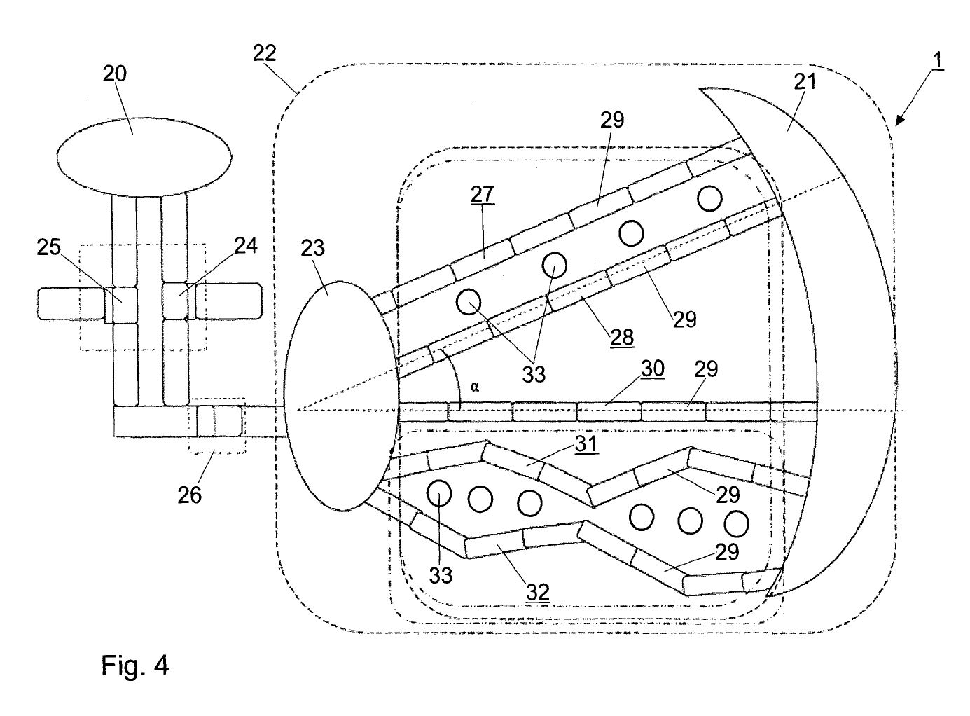

FIG. 4 a schematic view of the individual components of a thermoelectric component and a cooling element,

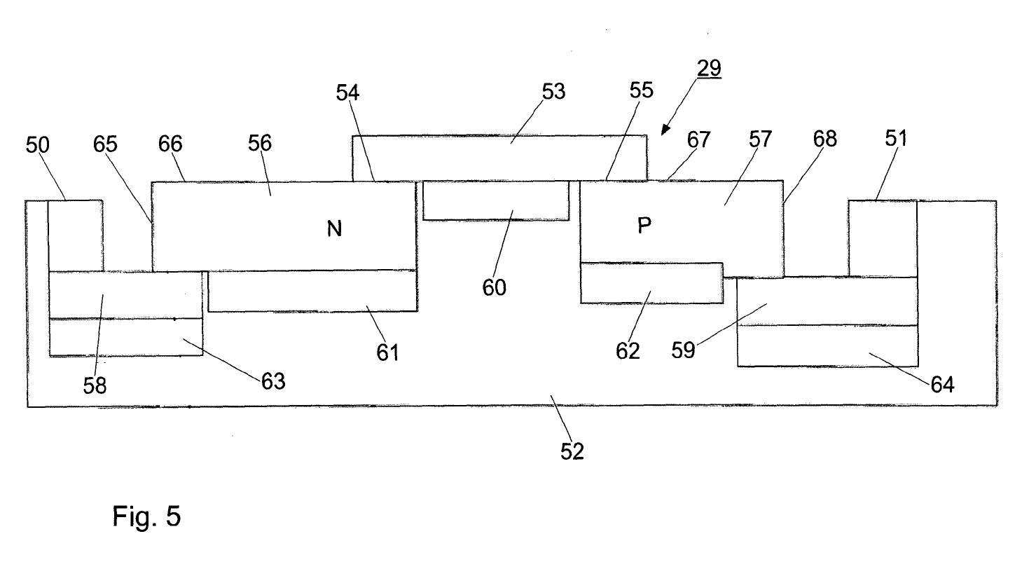

FIG. 5 a layer composition of a first embodiment with two cooling elements,

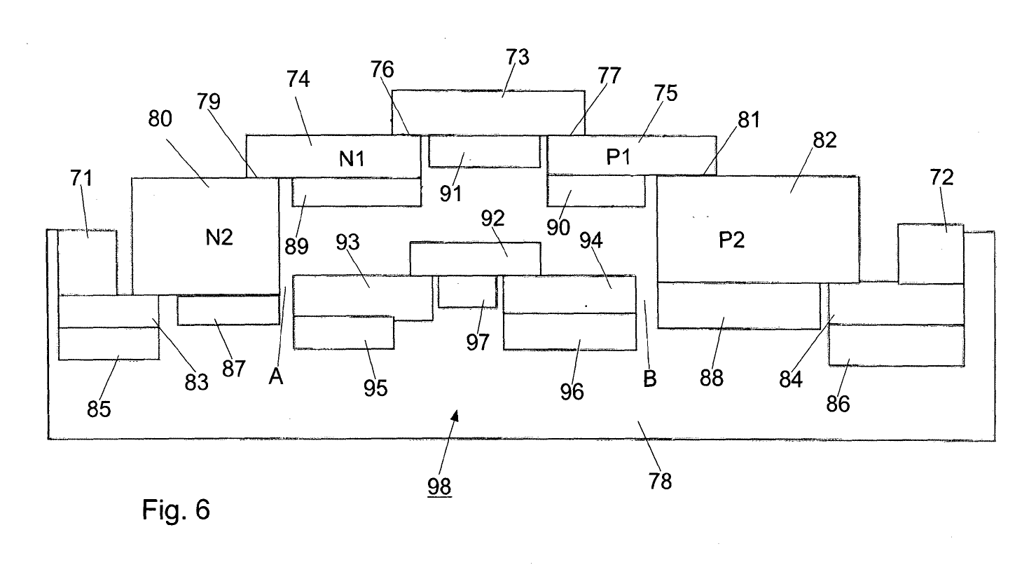

FIG. 6 a layer composition with three cooling elements,

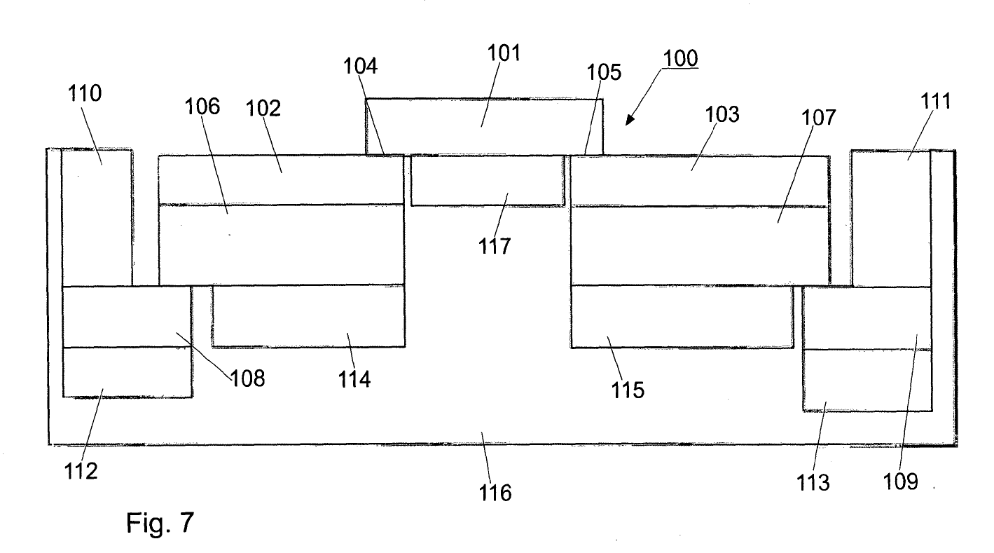

FIG. 7 a layer composition with two cooling elements as thermoelectric generators, and

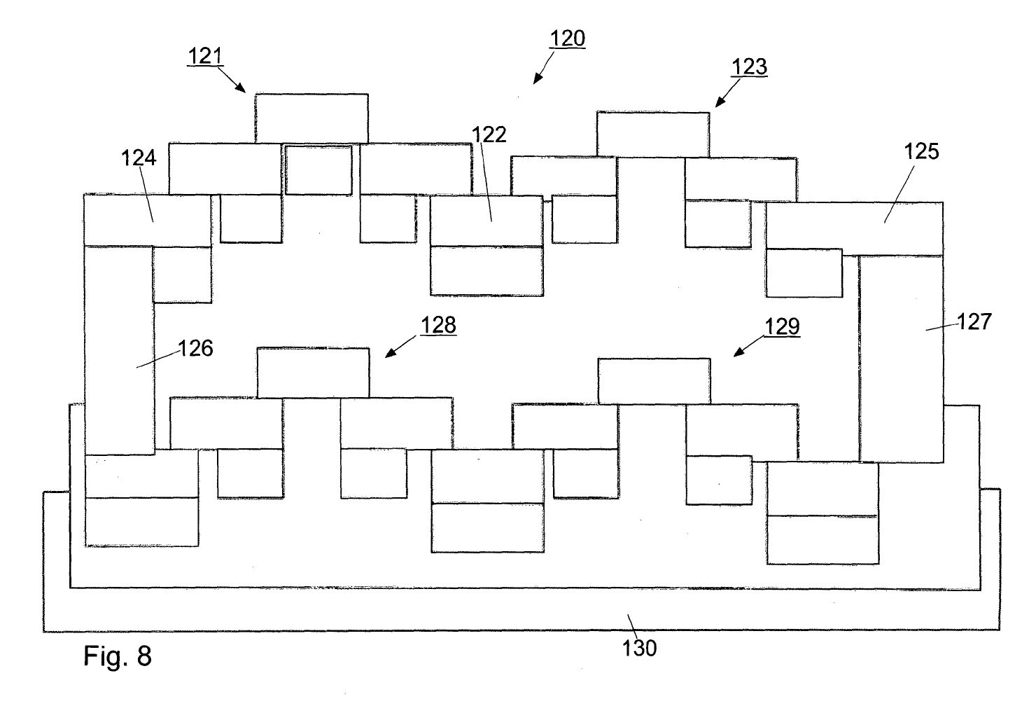

FIG. 8 a layer composition of a fourth embodiment with a total of four cooling elements.

FIG. 1 shows a circuit diagram with the individual components for the assembly of a thermoelectric component 1. A trigger unit 2 is connected with two transistors 4 through a trigger line 3, whereat the trigger unit 2 and the transistors 4 are supplied with a positive potential 5 by a voltage supply. The trigger unit 2 and the transistors 4 are parts of a control unit. On the output side of the transistor 4 a line 6 branches out, passes two protective diodes 7, 8 to a cooling element 15 each. The cooling elements 15 are thermal elements or cooling sections of a thermoelectric component. The protective diodes 7, 8 could, e.g., consist of Schottky protective diodes and direct the current flow into the direction of the cooling elements 15. Both of the cooling elements 15 are connected with the zero potential 9 on the one side, and are supplied with voltage by the transistors 4 through the two protective diodes 7,8 on the other side.

Due to the power supply it is achieved that the cooling elements 15 generate a cooling for cooling microelectronic components, e.g. those of a microprocessor. For this reason it is intended, that all components of the circuit diagrams are additionally integrated into an integrated circuit. This integration can occur at least once, preferably several times according to the embodiments of FIGS. 4 to 8. The occurring cooling results from the Peltier effect as is intrinsically known. The basis of the Peltier effect is the contact of two materials which have a different energy level of conduction bands, in particular a p-doped semiconducting material on the one side and a n-doped semiconducting material on the other one, which are electrically connected by a bridge element. Once electricity runs through two contact points of these semiconducting materials, which are arranged one after the other, heat energy has to be absorbed at one of the contact points in order to transport electrons into the energetic higher conduction band of the adjoining semiconducting material, so that a cooling effect occurs. In the other contact point the electrons fall from a higher to a lower energy level, so that in this case a cooling occurs at that spot where the electrons transfer from the n-doped semiconductor to the p-doped semiconductor.

FIG. 2 shows an integrated circuit 10 in a perspective schematic view, in which the structures of a microprocessor or similar components are integrated. Due to the high power consumption of a microprocessor, e.g., a considerable amount of heat develops, so that an additional cooling of the complete integrated circuit 10 does not only occur through a cooling system and a fan, but is additionally necessary within the integrated circuit 10. The invention at hand therefore suggests integrating at least one additional thermoelectric component 1 with at least one cooling element 15 into an integrated circuit 10, which is either arranged between the individual layers of the integrated circuit or which is arranged in the lowest or highest position of the integrated circuit 10. However, there is also the possibility to place several thermoelectric components 1 immediately below the individual components in an integrated circuit, for instance when said integrated circuit consists of several parallel running microprocessors, which are being temporarily switched on and off by a corresponding control logic, such as when a significant rise in temperature occurs and a partial shutdown or, if need be, cooling is required. Therefore, if microprocessors are integrated in multiple arrangements in an integrated circuit 10, each individual microprocessor can be assigned to such a thermoelectric component 1, whereat it may feature a simple structure, but may also be structured more complexly according to FIGS. 4 to 8. FIG. 2 merely shows one position of the thermoelectric component 1 by means of the dotted line in a schematic view, but which was chosen arbitrarily and may be changed within the integrated circuit 10 at will.

FIG. 3 shows a temperature-time diagram of a typical cooling flow for a cooling element 15. The temperature of a cooling element 15 drops from a temperature of above 0° to as low as −30°, until the temperature further stabilizes at a value of about −15°. In order to take advantage of the extreme cooling temperature, the cooling element 15 is only supplied with voltage in the active phase until a point of time x when a temperature of −30° is reached. The cooling element 15 is then transferred into a resting phase, whereas a second or one further cooling element 15 after the other is supplied with power, in order to use the cooling effect repeatedly. By using several individual cooling elements 15, the maximal temperature drop during an active phase 16 can be used to cool down an integrated circuit, while the cooling element 15 adjusts to the surrounding temperature during the rest phase 17. Insofar as several cooling elements 15 are used in that way a continuous cooling can be achieved in spite of the regulating temperature of the cooling element 15 in order to realize a cooling of below −15°.

FIG. 4 shows a schematic view of the assembly of a thermoelectric component 1 according to the invention with at least one cooling element 15, as it is to be realized within an integrated circuit, such as a microprocessor. The thermal elements 29 of FIG. 4 correspond to the cooling element 15 of FIG. 1. In order to apply voltage, a first contact area 20 is formed, which is supplied with a positive voltage under normal circumstances. A second contact area 21, on the other hand, is connected to the zero potential, whereat the contact area 21 is dimensioned so that contacting of the cooling element 15 becomes possible. The thermoelectric component 1 within the integrated circuit consists of a first contact area 22, which is meant as a contact for the zero potential and features cooling sections 27, 28, 30, 31, 32. A voltage supply occurs through the first contact area 20 by two transistors 24, 25 switched in parallel, which are simultaneously or subsequently switched for power supply in order to reduce the starting current. The current may be interrupted through an additional circuit element 26. An interruption of the current can occur when a part of the integrated circuit is permanently inactive, or a targeted thermoelectric component 1 may be switched on during a rise in temperature within the integrated circuit to cool down the temperature. The electric current within such a thermoelectric component 1 occurs through a first contact area 22, the cooling sections 27, 28, 30, 31, 32 and the second contact area 23. The first contact area 22 is connected electrically to the second contact area 23 through cooling sections, whereat three different connections are shown in FIG. 4.

With a first embodiment the first contact area 22 can be connected to the second contact area 23 through several parallel running cooling sections arranged in equidistant distances, whereat the individual cooling sections 27, 28 consist of thermal elements 29. When the cooling sections 27, 28 run parallel in equidistant distances, a constant cooling of the temperature of an area is achieved. Additional sensor elements 33 may be arranged between the individual cooling sections 27, 28, which trigger a switching process depending on the present temperature gradients, such as interrupting or engaging the current supply to the first contact area 22. The arrangement of a first contact area 22, a second contact area 23, the cooling sections 27, 28 and the thermal elements 29 may be arranged in layers above each other.

Alternatively, there is the possibility to arrange the cooling sections under an angle α, so that a first cooling section 28 and a second cooling section 30 exist, whereat due to the given angle and the varying distance between the cooling sections 28, 30 a quicker cooling is achieved in the proximity of the first contact area 22, while a noticeably slower cooling occurs with a growing distance, particularly in the proximity of the second contact area 23. This arrangement shows a second embodiment, which may also be arranged in multiple arrangements in layers above each other.

Alternative, there is the possibility to electrically connect the first contact area 22 with the second contact area 23 through two thermoelectric cooling sections 31, 32. In that case a varying temperature drop is achieved due to the periodically changing distance of the two cooling sections 31, 32. With this embodiment, the third example of FIG. 4 is shown. As with the first example, temperature sensors 33 may be used with the second and third examples, whereat said temperature sensors 33 allow for a selective voltage supply of the cooling sections 31, 32 through a control unit.

FIG. 5 shows a schematic view of a thermal element 29 in a layered arrangement, whereat generally several thermal elements 29 may be arranged next to each other and/or above one another in a semiconducting chip. Here the further possibility of electrically running individual thermal elements 20 in series or in parallel exists, in order to use the Peltier effect on the one hand and to deliberately cool a region of the integrated circuit through several thermal elements 29.

With two electric contact areas 50, 51 there is the possibility of connecting an individual thermal element 29 with further thermal elements 29 in parallel or in series or to use said contact areas 50, 51 for voltage supply. The entire arrangement is embedded in a substrate 52 here, which can hold a plurality of similar thermal elements 29, and additionally holds the individual microelectronic components of, e.g., a microprocessor, whereat a direct allocation of the thermal elements 29 to the structure of the microprocessor may be intended, so that a targeted cooling may occur in those areas emitting a lot of heat.

The thermal element 29 consists in addition to the two contact areas 50, 51 of a first upper bridge element 53, which is connected to a p- or n-doped semiconducting material through a contact area 54, 55. The p-doped semiconducting material 56 is electrically connected through a lower bridge element 58 with the first contact area 50, while the n-doped semiconducting material 57 is connected to the second electric contact area 51 through a second lower bridge element 59. Depending on the direction of the current, a reverse doping of the semiconducting materials 56, 57 may occur. Each individual component of the thermal element 29 is connected to the substrate 52 through an adhesive layer 60, 61, 62, 63, 64.

Furthermore, this elementary arrangement of a thermal element 29 shows a distinctive feature, namely such, that both doped semiconducting materials 56, 57 are connected with the upper bridge element 53 through the contact areas 54, 55 with different dimensions, without the need for adapting the form of the doped semiconducting materials 56, 57. The contact areas 54, 55 can already be varied by having the semiconducting materials 56, 57 be arranged out of alignment in regard to the upper bridge 53. Here the rule applies, that the bigger the contact areas 54, 55, the smaller the heat transport. The heat dissipation occurs through the exposed areas 65, 66 of the first doped semiconducting material 56 or the respective areas 67, 68 of the second doped semiconducting material 57. This simple structure of a thermal element 29 is also the basis for further, more complex embodiments.

FIG. 6 shows the assembly of a thermoelectric cooling array 70 consisting of several thermal elements 29 in a schematic view. The cooling array 70 also features a first contact area 71 and a second contact area 72, which is either used for connecting different cooling arrays 70 with each other or for voltage supply. A first n-doped semiconducting material 74 and a second p-doped semiconducting material 75 are connected through an upper bridge element 73, whereat the connection occurs through differently sized contact areas 76, 77. The background to this is that when considering the current through the smaller contact area 76 more heat is emitted up, i.e. to be emitted from the substrate 78, while the larger contact area 77 emits less heat down into the substrate 78. The first n-doped semiconductor material is further connected to a second n-doped semiconductor material 80 through a contact area 79, while the p-doped semiconductor material 75 is connected to a further p-doped semiconductor material 82 through a contact area 81. Due to the two step-lined n- or p-doped semiconducting materials 74, 75, 80, 82 a higher cooling capacity is achieved.

For the first p-doped semiconducting materials 74, 75 Bi₂Te₃, BN, TiN, SiGeN, PbTeN, e.g., is used as a base material, and the same materials can be used as base material for the second n-doped semiconducting materials 80, 82. In general, the base material to be used for the p-doped and n-doped semiconducting materials depend on the operating temperature of the integrated circuit cooling array. The second n-doped semiconducting materials 80, 82 are again connected with a first contact area 71 or respectively with the second contact area 72 through a lower bridge element 83, 84, so that a current flow through the conducting layers can be achieved. The lower bridges 82, 84 are connected with the substrate 78 through an adhesive layer 87, 88, while the first doped semiconducting materials 74, 75 are connected through an adhesive layer 89, 90 and the upper bridge element 73 is connected with the substrate 79 through an adhesive layer 91. The alternative shown here additionally features a further bridge element 92, which connects a first p-doped semiconducting material 93 and a second n-doped semiconducting material 94, which are in return connected with the substrate 78 though adhesive layers 95, 96, 97. A direct electric contacting of these third doped semiconducting materials 93, 94 is not available, in contrast to the other arrangement. The third semiconducting materials 93, 94 are embedded in the substrate 78, which is dielectric. The distance A between the second doped semiconducting material 80 and the third doped semiconducting material 93 and the distance B between the second doped semiconducting material 82 and the third doped semiconducting material 94 was chosen to be unequal, but was kept so small, that the substrate 78 becomes conductive for this short distance for temperatures around −30° and thus a voltage supply of the additional thermal element 98 occurs. This way it can be achieved, that with a cooling of about −30° in spite of the resulting effect of a subsequent rise in temperature, due to the additional cooling the temperature of about −30° can be maintained for a longer period of time.

FIG. 7 shows a schematic arrangement of a thermoelectric generator 100 according to the Seebeck effect. The thermoelectric generator 100 consists of an upper bridge element 101, which is connected to a first n-doped semiconducting material 102 and a first p-doped semiconducting material 103 through contact areas 104, 105. The first doped semiconducting materials 102, 103 are connected to a second n-doped semiconducting material 106 and a second p-doped semiconducting material 107. The first semiconducting materials 102 and 103 and the respective second semiconducting materials 106, 107 are fully in contact in this case. The second semiconducting materials 106, 107 are connected with a first contact area 110 and a second contact area 111 through a lower bridge element 108. The contact areas 110, 111 are again used for connecting the individual thermoelectric generator elements 100, or to tap a voltage. The lower bridge elements 108 and 109 are connected through an adhesive layer 112, 113 and the second doped semiconducting materials 106, 107 are connected through an adhesive layer 114, 115 with a substrate 116, while the upper bridge element 101 is connected with the substrate 116 through an adhesive layer 117.

FIG. 8 shows a multiple arrangement of thermal elements, which are set up together to form a cooling array 120 in a schematic overview. A first thermal element 121 is connected with a second thermal element 123 is connected through a bridge element 122. The assembly of each individual thermal element 121, 123 corresponds to the assembly of the thermal element according to FIG. 4. A voltage supply can occur through a first contact area 124 and a second contact area 125. Both contact areas 124, 125 are connected with two further thermal elements 128, 129 through a dielectric compound layer 126, 127, so that a quadruple arrangement of thermal elements is available. The two upper thermal elements 121, 123 are switched in series in this case, as are the two lower thermal elements 128, 129. The upper thermal elements 121, 123 are also switched in parallel with the lower thermal elements 128, 129 through the electrical compound layer 126, 127, so that any thermal elements 121, 123, 128, 129 are activatable. The advantage of this arrangement is that the lower arrangement of thermal elements 128, 129 are switched on only with a corresponding cooling, so that a lower starting current develops due to the delayed connection.

All four thermal elements 121, 123, 128, 129 are integrated in a substrate 130 and are each connected with the substrate 130 through adhesive layers.

The thermoelectric generator 100 is to be used for additional generation of voltage in this case, due to the waste heat produced by the integrated circuit. The waste heat produced results in a generation of voltage in the thermoelectric generator 100 due to the Seebeck effect, and can be used within the integrated circuit for the supply of thermal elements. Such a thermoelectric generator 100 can therefore preferably be used in the upper layers of the integrated circuit in order to use the resulting waste heat.

### LIST OF REFERENCES

1 thermoelectric component

2 trigger unit

3 trigger line

4 transistor

5 positive potential

6 line

7 protective diode

8 protective diode

9 zero potential

10 integrated circuit

15 cooling element

16 active phase

17 rest phase

20 first contact area

21 second contact area

22 first contact area

23 second contact area

24 transistor

25 transistor

26 circuit element

27 cooling section

28 cooling section

29 thermal element

30 cooling section

31 cooling section

32 cooling section

33 sensor

50 contact area

51 contact area

52 substrate

53 bridge element

54 contact area

55 contact area

56 semiconducting material

57 semiconducting material

58 bridge element

59 bridge element

60 adhesive layer

61 adhesive layer

62 adhesive layer

63 adhesive layer

64 adhesive layer

65 area

66 area

67 area

68 area

70 cooling array

71 contact area

72 contact area

73 bridge element

74 semiconducting material

75 semiconducting material

76 contact area

77 contact area

78 substrate

79 contact area

80 semiconducting material

81 contact area

82 semiconducting material

83 bridge element

84 bridge element

85 adhesive layer

86 adhesive layer

87 adhesive layer

88 adhesive layer

89 adhesive layer

90 adhesive layer

91 adhesive layer

92 bridge element

93 semiconducting material

94 semiconducting material

95 adhesive layer

96 adhesive layer

97 adhesive layer

98 thermal element

100 thermoelectric generator

101 bridge element

102 semiconducting material

103 semiconducting material

104 contact area

105 contact area

106 semiconducting material

107 semiconducting material

108 bridge element

109 bridge element

110 contact area

111 contact area

112 adhesive layer

113 adhesive layer

114 adhesive layer

115 adhesive layer

116 substrate

117 adhesive layer

120 cooling section

121 thermal element

122 bridge element

123 thermal element

124 contact area

125 contact area

126 compound layer

127 compound layer

128 thermal element

129 thermal element

130 substrate

A distance

B distance

1. Integrated circuit cooling array, preferably for a microprocessor or cooling apparatus, consisting of a dielectric substrate with doped and distinguished areas for the realization of at least one thermoelectric component forming a cooling array,
wherein
the thermoelectric component comprises at least one first contact area, at least one second contact area and at least one cooling section, whereat the cooling section is arranged between the first and the second contact area and consists of at least one thermal element, which is supplied with voltage by the first contact area and the second contact area through a control unit, and whereat the thermal element consists of at least one first doped layer and at least one second doped layer, which are in such a way connected by a bridge element that the bridge element rests only partially on the first doped layer and/or the second doped layer.

2. Integrated circuit cooling array according to claim 1,
wherein
a length of a section of the bridge element resting on the first or second doped layer x, a length of the first or second doped layer y and a width of the first or second doped layer z comply with the conditions 0.2≤x/y≤0.5 and z≥x.

3. Integrated circuit cooling array according to claim 1,
wherein
a cooling section consists of several thermal elements, which are each connected in series between the first and the second contact area, and/or in that a cooling section consists of several thermal elements which are each connected in series between the first and the second contact area and additional thermal elements are at least partially connected in parallel with individual thermal elements.

4. Integrated circuit cooling array according to claim 1,
wherein
the contact areas between the bridge element and the first and second doped layer differ from each other in regard to size.

5. Integrated circuit cooling array according to claim 1,
wherein
the thermoelectric component is arranged on the substrate or within the substrate.

6. Integrated circuit cooling array according to claim 5,
wherein
several thermoelectric components exist, which are arranged next to each other and/or above one another within the substrate, and/or that several adjoining thermoelectric components are arranged on the substrate.

7. Integrated circuit cooling array according to claim 6,
wherein
several thermoelectric components are arranged above each other, whose first and second contact areas are connected by at least one permanent or switchable VIA-connection (Vertical Interconnect Access), whereat the switching of a VIA-connection occurs through the control unit.

8. Integrated circuit cooling array according to claim 1,
wherein
several cooling sections are arranged to run parallel between the first and the second contact area.

9. Integrated circuit cooling array according to claim 1,
wherein
each cooling section is to be supplied with voltage independently of the other ones.

10. Integrated circuit cooling array according to claim 1,
wherein
at least two cooling sections exist, which run in a horizontal angle to each other or at least two cooling sections exist, which run in a periodically alternating distance to each other.

11. Integrated circuit cooling array according to claim 1,
wherein,
the horizontal angle between two thermal elements of a cooling section or between two cooling sections or between two segments of two cooling sections measures between 5° and 85°, preferably between 30° and 40°, and particularly preferably between 10° and 20°.

12. Integrated circuit cooling array according to claim 1,
wherein
several thermal elements or cooling sections of a thermoelectric component are arranged above each other in the substrate.

13. Integrated circuit cooling array according to claim 1,
wherein
a first contact area and several second contact areas exist, whereat at least one cooling section each is arranged between the first contact area and the several second contact areas, and/or in that the first contact area is surrounded by several second contact areas, whereat at least one cooling section each is arranged between the first contact area and the second contact areas.

14. Integrated circuit cooling array according to claim 1,
wherein
several cooling sections extend from the first contact area in the form of a star structure to a second contact area surrounding the first contact area or to several second contact areas surrounding the first contact area.

15. Integrated circuit cooling array according to claim 1,
wherein
temperature sensors are arranged between at least two cooling sections, which interact with the control unit.

16. Integrated circuit cooling array according to claim 9,
wherein
the control unit comprises a circuit element for the selective voltage supply of one of several thermoelectric components or one of several cooling sections.

17. Integrated circuit cooling array according to claim 1,
wherein
the control unit comprises a transistor, which supplies voltage through a blocking diode to the thermoelectric component, or in that the control unit comprises several transistors, which are connected in parallel and each supply voltage through a blocking diode to a thermoelectric component simultaneously or at staggered intervals in regard to other thermoelectric components.

18. Integrated circuit cooling array according to claim 7,
wherein
the control unit switches existing switchable VIA-connections independently from each other.

19. Integrated circuit cooling array according to claim 18,
wherein
the control unit comprises a programmable device with a high frequency pulse generator and a counting unit, which can be triggered by the pulse generator, whereat the VIA-connection between at least two thermoelectric components is switched in relation to the counter value of the counting unit by the control unit.

20. Integrated circuit cooling array according to claim 1,
wherein
the first doped layer of a thermal element is an n-doped layer, and in that the second doped layer of a thermal element is a p-doped layer.

21. Integrated circuit cooling array according to claim 1,
wherein
the bridge element consists of a highly polysilicon, a metal or a metal alloy.

22. Integrated circuit cooling array according to claim 1,
wherein
at least one shielding layer exists, which is arranged to adjoin to the warmer side of a thermoelectric component.

23. Integrated circuit cooling array according to claim 22,
wherein
the shielding layer comprises an electrically isolating material, whereat the isolating material consists of a high-k and/or low-k dielectric medium, in particular silicon dioxide, AgO, TiO₂, HfO₂ or Al₂O₃.

24. Integrated circuit cooling array according to claim 1,
wherein
at least one cooling layer exists, which contacts at least one bridge element on the cooler side of a thermoelectric component, which consists of a heat conductive material.

25. Integrated circuit cooling array according to claim 1,
wherein
the integrated circuit comprises at least one functional unit, which is arranged between the thermoelectric component and/or between cooling sections of a thermoelectric component and/or which is arranged at the warmer or cooler side of a cooling section.

26. Integrated circuit cooling array according to claim 25,
wherein
the functional unit comprises
a sensor, in particular a heat sensor or optical sensor,
a rectifier, in particular a diode,
a switching element, in particular a transistor, preferably a MOSFET such as IGFET, NMOS, PMOS, VMOS,
a control element,
a programmable device, in particular a microprocessor, a microcontroller or a programmable logic such as FPGA or PLD,
a memory element, such as DRAM, ROM, SRAM,
a solar panel,
a laser diode,
a light-emitting diode or
a micro strip.

27. Integrated circuit cooling array according to claim 5,
wherein
a thermoelectric component is arranged on the substrate or within one of the top layers of the substrate, whereat the waste heat of the microelectronic components are used for generating voltage.

28. Integrated circuit cooling array according to claim 1,
wherein
the integrated circuit is designed for total electric currents between 0.5 pA and 500 mA, in particular between 1 mA and 200 mA, preferably between 20 μA and 120 μA and particularly preferably between 10 μA and 1 μA.

29. Integrated circuit cooling array according to claim 1,
wherein
an intermediate layer is arranged between to thermoelectric components arranged above each other in the substrate, which determines a distance between the thermoelectric components.
